(19) United States
(12) Patent Application Publication
(10) Pub. No.: US 2002/0001361 A1
(43) Pub. Date: Jan. 3, 2002

(54) Semiconductor integrated circuit and optical transfer unit

(75) Inventors: Satoshi Ueno, Ome (JP); Kiyoshi Hayashi, Takamatsu (JP); Takashi Harada, Hidaka (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 09/886,027

(22) Filed: Jun. 22, 2001

(30) Foreign Application Priority Data
Jun. 30, 2000 (JP) 2000-197922

(51) Int. Cl. H03D 3/24

(52) U.S. Cl. 375/376

(57) ABSTRACT

In a semiconductor integrated circuit comprising a PLL circuit including an LC resonance type voltage-controlled oscillator which oscillates at the oscillation frequency depending on the control voltage applied, a phase comparator PHC for comparing the phase of an oscillation output signal φ b of said voltage-controlled oscillator with the phase of the reference clock φ r, and a loop-filter LPF for outputting a voltage depending on the phase difference based on an output of the phase comparator PHC, this semiconductor integrated circuit further comprises a plurality of voltage-controlled oscillators VCO1, VCO2, . . . which include different center frequencies of the frequency variable range and the selecting unit for selecting only one oscillator from a plurality of said voltage-controlled oscillators VCO1, VCO2, . . . Accordingly, the semiconductor integrated circuit comprising the PLL circuit using the LC resonance type voltage-controlled oscillator having excellent phase noise characteristic and assuring the desired frequency variable range can be manufactured with higher manufacturing yield.

### BACKGROUND OF THE INVENTION

The present invention relates to a technology that is usefully applicable to a semiconductor integrated circuit comprising a PLL (Phase Locked Loop) circuit, for example, to a technology that is usefully applicable to a clock generating circuit for synchronous transfer in an optical transfer unit for transmitting a high-speed data signal used in the optical transfer.

In a semiconductor integrated circuit, a PLL circuit is incorporated in some cases to obtain an operation clock signal and a timing signal.

In a PLL circuit mounted on a semiconductor chip, a multivibrator or ring oscillator has generally been employed as a voltage-controlled oscillator. Moreover, in recent years, an LC resonance type voltage-controlled oscillator has also been employed in some cases mainly in the field of a high frequency circuit using the technology to form an inductor on a semiconductor chip.

By the way, since an optical transfer unit processes a signal in the frequency as high as 10 GHz, only a small jitter of the operation clock will give influence on deterioration of signal waveform. Therefore, a low jitter operation clock is required. Particularly, when such transfer unit is used in the repeating system of the optical transmission line, request for reduction of jitter in the operation clock is firm because deterioration of signal waveform is accumulated in every repeating process.

If a phase noise characteristic is bad, the PLL circuit will generate the clock including large jitter. Therefore, in order to generate the clock with low jitter, it is required to use a voltage-controlled oscillator having the excellent phase noise characteristic. Moreover, it is desirable for the PLL circuit to assure wide variable range of frequency. However, the voltage-controlled oscillator of the multivibrator type and ring oscillator type has a demerit that the variable range of oscillation frequency is wide but phase noise characteristic is rather bad. Meanwhile, the voltage-controlled oscillator of the LC resonance type uses a variable capacitance diode as a capacitor and therefore has the property that the variable range of oscillation frequency is narrow but has excellent phase noise characteristic.

Moreover, a voltage-controlled oscillator using a crystal oscillator can also be considered as the oscillator having the excellent phase noise characteristic, but in the case where the oscillator of this type is used, the voltage-controlled oscillator is constituted outside a chip as a discrete element and thereby a module size of optical transfer unit increases, resulting in the rise of cost of such module.

On the occasion of integrating the voltage-controlled oscillator into a semiconductor chip, it is not a rare case that the variable range of oscillation frequency is deviated from that estimated in the design stage due to fluctuation of process even if the oscillator is of the multivibrator type, ring oscillator type and LC oscillation type. When the frequency variable range is deviated, a problem that the desired oscillation frequency cannot be obtained in the variable range near the upper limit or lower limit thereof occurs.

Particularly when the LC resonance type voltage-controlled oscillator assuring narrow frequency variable range is used, it is difficult to obtain a constant capacity due to fluctuation of PN junction characteristic because the PN junction capacity is used as a capacitor and moreover since the variable range of capacity is not so wide, if the variable capacitance range is deviated due to the fluctuation of process, the necessary oscillation frequency cannot be obtained as the voltage-controlled oscillator, generating a problem that yield of the PLL circuit is lowered.

Moreover, as the other approach of the voltage-controlled oscillator, a technology has been proposed in which a couple of voltage-controlled oscillators having the center frequencies which are different to a large extent from each other with the desired frequency being in an intermediate position between these frequencies, and these oscillators are combined to form a voltage-controlled oscillator having a wider frequency variable range. However, this voltage-controlled oscillator has a demerit that the phase noise characteristic is lowered in comparison with that of the voltage-controlled oscillator which is formed of a discrete unit.

Moreover, in the oscillator formed by combining a couple of voltage-controlled oscillators, when the frequency variable range of each voltage-controlled oscillator is deviated in the same direction, the frequency variable range obtained after the combination is also deviated in the same direction. Since the element characteristics are deviated in the same direction in the semiconductor integrated circuit when the elements of the same type are formed adjacently on one chip, the method to combine a couple of voltage-controlled oscillator cannot solve the problem that the variable range of oscillation frequency is deviated depending on the process.

### SUMMARY OF THE INVENTION

An object of the present invention is to provide a semiconductor integrated circuit comprising a PLL circuit to obtain a highly accurate oscillation signal of desired frequency even in the case where a variable control range of a voltage-controlled oscillator is deviated depending on processes.

Moreover, another object of the present invention is to provide a semiconductor integrated circuit comprising a PLL circuit using an LC resonance type voltage-controlled oscillator having excellent phase noise characteristic and enabling control in the desired frequency range.

The further object of the present invention is to provide an optical transfer unit that can be manufactured in the high manufacturing yield, while waveform deterioration of optical transfer signal is reduced with operation clock including a small amount of jitter.

The aforementioned and other objects and novel features of the present invention will become apparent from the description of the present specification and the accompanying drawings.

The typical inventions of the present invention disclosed in this specification will be explained below.

In a semiconductor integrated circuit including a voltage-controlled oscillator which executes oscillating operation in a frequency depending on a control voltage to be applied and a phase comparator which compares a phase of an oscillation output signal of the voltage-controlled oscillator with a phase of a reference frequency signal and also comprising a PLL circuit (phase locked loop) in which an output voltage of the circuit for outputting a voltage depending on a phase difference based on an output of the phase comparator is applied to the voltage-controlled oscillator in order to control the oscillation frequency of the voltage-controlled oscillator, the voltage-controlled oscillator is constituted by providing a plurality of resonance type oscillators in different center frequencies of the frequency variable range including a resonance circuit having an inductor and a capacitor and a selecting means for selecting one oscillator from among the resonance type oscillators.

According to the above means, even if the frequency characteristic of the voltage-controlled oscillator is deviated due to the fluctuation of process, a voltage-controlled oscillator satisfying the desired frequency characteristic can be found in the higher probability from a plurality of voltage-controlled oscillator with their center frequencies different from one another. Therefore, even when the LC resonance type voltage-controlled oscillator assuring excellent phase noise characteristic and narrow frequency variable range is employed, the PLL circuit having excellent phase noise characteristic and desired frequency characteristic can be manufactured in higher yield by utilizing a voltage-controlled oscillator having the desired frequency variable range using the selecting means.

Preferably, a plurality of resonance type oscillators are recommended to have the frequency variable ranges which are continuous or overlapped with each other. An oscillator having the characteristic near the desired one may be formed within a plurality of resonance type oscillator by forming a plurality of resonance type oscillators explained above.

In more practical, the inductor is a spiral type inductor which is formed of the wiring formed in the spiral shape on a semiconductor substrate and a capacitor (condenser) is a variable capacitance diode consisting of PN junction connected in an inverse direction.

The present invention can be adapted to any type of voltage-controlled oscillator such as multivibrator type and ring oscillator type as well as the LC resonance type oscillator. Namely, the present invention has a structure comprising a plurality of voltage-controlled oscillators (of the multivibrator type or ring oscillator type) that are designed to assure different center frequencies of the frequency variable range and continuity or overlap of the frequency variable range and a selecting means for selecting only one oscillator from a plurality of voltage-controlled oscillators explained above. Accordingly, the PLL circuit having the desired control range can be obtained with higher yield.

It is preferable to provide a structure that a fuse circuit having a plurality of fuses corresponding to a plurality of resonance type oscillators is provided as a selecting means, any one of the fuses of the fuse circuit explained above is broken through disconnection or conduction and thereby the supply of power of the other resonance type oscillators is suspended, except for only one oscillator.

According to this structure, since use of an any resonance type oscillator is fixed and the other resonance type oscillator operation is disabled depending on the setting of the fuse circuit, a user of the semiconductor integrated circuit is not requested to newly select the voltage-controlled oscillator and thereby it is possible to avoid occurrence of a fault such as selection error. Moreover, since the power is no longer supplied to the voltage-controlled oscillator not used, it can also be avoided that a characteristic of the PLL circuit is deteriorated and noise is generated through the resonance.

In more practical, a power-supply transistor is respectively provided in a plurality of resonance type oscillators, and the fuse circuit is constituted to set the power-supply transistor of the resonance type oscillator corresponding to the broken fuse to the power feeding-condition, while the power-supply transistor of the resonance type oscillator corresponding to the normal fuse to the non power-feeding condition.

Moreover, the output sides of a plurality of resonance type oscillators are respectively provided with buffer circuits for waveform shaping and the fuse circuit is structured to disable the operation of a plurality of buffer circuits corresponding to the resonance type oscillators, except for only one buffer circuit.

It is more preferable that the selecting means is constituted to provide a selector circuit which supplies an output of a resonance type oscillator to a PLL circuit depending on the control signal, and an output of the other resonance type oscillator is cut off. With the means explained above, it is possible to avoid the fault that characteristic of the PLL circuit is deteriorated and noise is generated through resonance of the resonance type oscillators not used.

### BRIEF DESCRIPTION OF THE DRAWINGS

FIG. 1 is a block diagram illustrating a schematic structure of an optical transfer module comprising an optical transfer unit.

FIG. 2 is a block diagram illustrating a schematic structure of a PLL circuit comprised in the optical transfer unit.

FIG. 3 is a block diagram illustrating the detail in the periphery of a voltage-controlled oscillator of the PLL circuit.

FIG. 4 is a circuit diagram illustrating an example of structure of the LC resonance type voltage-controlled oscillator and a buffer circuit.

FIG. 5 is a diagram illustrating an example of the structure of cross-sectional view of a varactor diode.

FIGS. 6(A-1) to 6(C-2) are explanatory diagrams illustrating changes of oscillation frequency of each voltage-controlled oscillator due to fluctuation of capacitance.

FIG. 7 is a circuit diagram illustrating an example of an LC resonance type voltage-controlled oscillator using MOS capacitance.

FIG. 8 is a circuit diagram of a selector circuit of FIG. 3.

FIG. 9 is a diagram illustrating an example of structure of a fuse switch circuit of FIG. 3.

FIGS. 10(a) to 10(c) are diagrams illustrating examples of modification of the fuse switch of FIG. 9.

FIG. 11 is a flowchart illustrating the processing sequence for selecting a voltage-controlled oscillator in the probe test.

### DESCRIPTION OF THE PREFERRED EMBODIMENTS

The preferred embodiments of the present invention will be explained with reference to the accompanying drawings.

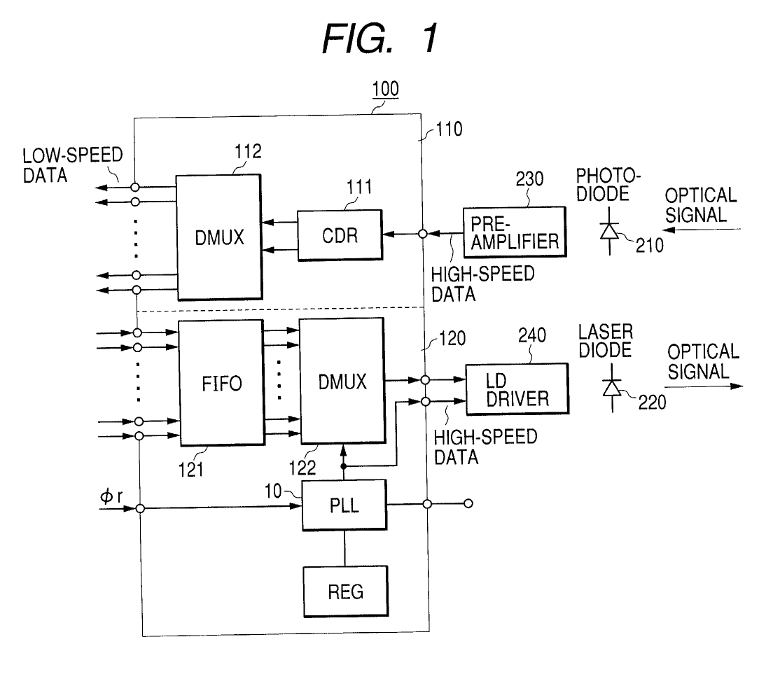

FIG. 1 is a block diagram illustrating a schematic structure of an optical transfer module comprising an optical transfer/receive unit of the present invention.

In FIG. 1, the reference number 100 is an optical transfer transceiver for high-speed transmission of signal of a plurality of channels with only one transmission line through the time division multiplex system and for demultiplexing the signal received, on the contrary, from the transmission line into the signal of each channel; 210, a photo-diode for converting an optical signal into an electric signal; 220, a laser diode for converting an electric signal into an optical signal; 230, a pre-amplifier for shaping the waveform of a high-speed electric signal obtained through the photo-electric conversion; and 240, a driver chip for driving the laser diode 220.

The optical transfer transceiver 100 is formed by forming a receiving circuit 110 and a transmitting circuit 120 on a semiconductor chip such as a single crystal silicon. The receiving circuit 110 is formed of a CDR (Clock & Data Recovery) circuit 111 for shaping the waveform of the received data signal and generating a clock by extracting a change of the received data signal and a demultiplexer 112 for demultiplexing the multiplexed receiving data of 16-channel into the data signal of each channel.

The transmitting circuit 120 is comprised of a buffer memory 121 of FIFO(first-in first-out) system for absorbing fluctuation of the input timing of the data signal, a multiplexer 122 for multiplexing the input data signal of 16-channel into one data signal through the time division multiplexing method and a PLL circuit 10 for supplying the operation clock of the multiplexer 122 and LD driver chip 240 of the successive stage through synchronization with the reference clock φ r as the externally inputted reference signal or reference clock.

This optical transfer transceiver 100 processes the signal, for example, of 10 GHz as the high-speed data signal for optical transfer. Therefore, the PLL circuit is required to generate an operation clock of 10 GHz with a small jitter.

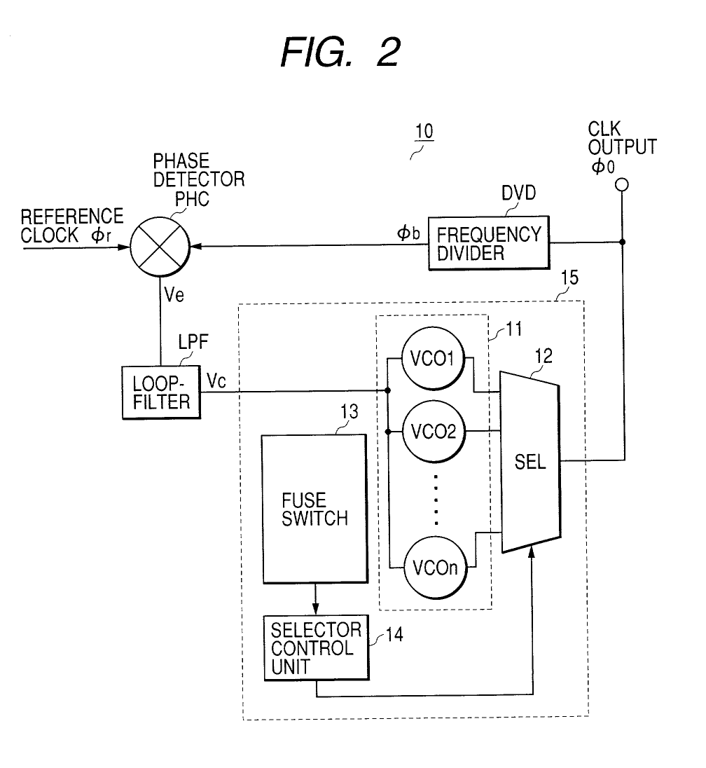

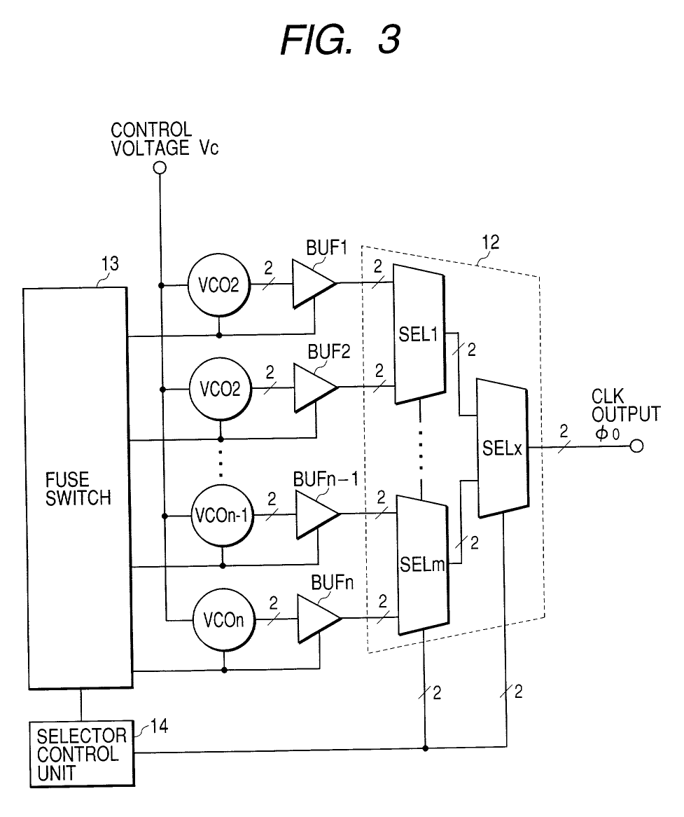

FIG. 2 is a block diagram illustrating a schematic structure of the PLL circuit 10 and FIG. 3 is a block diagram of the periphery of the voltage-controlled oscillator of the PLL circuit 10.

The PLL circuit 10 of the present invention can attain the desired high yield characteristic by forming a plurality of voltage-controlled oscillators VCO1 to VCOn on a semiconductor chip to operate the oscillator which satisfies in the highest level the requirement of the frequency characteristic among such voltage-controlled oscillators VCO1 to VCOn and not to operate the other oscillators even when the characteristic of the voltage-controlled oscillators are deviated due to fluctuation of processes.

As illustrated in FIG. 2 and FIG. 3, the PLL circuit 10 is comprised of a VCO forming part 11 in which a plurality of voltage-controlled oscillators VCO1 to VCOn are formed, a selector 12 for selecting and outputting an output of a voltage-controlled oscillator among a plurality of voltage-controlled oscillators VCO1 to VCOn, a fuse switch circuit 13 for setting each voltage-controlled oscillator to operation enabling condition or to operation disabling condition, a VCO selecting part 15 providing the selector control unit 14 for outputting a selection control signal to the selector 12 depending on the condition of fuse switch circuit 13, a frequency divider DVD for dividing (for example, dividing into 1/16) the oscillation signal φ 0 outputted from the voltage-controlled oscillator, a phase detector PHC for comparing the phase of a frequency-divided signal φ b with a reference clock φ r inputted from the outside of chip and a loop filter LPF for generating a voltage depending on the phase difference based on the signal Ve outputted from the phase detector PHC or the like. The control voltage Vc outputted from the loop filter LPF is impressed to the frequency control terminal of the voltage-controlled oscillators VCO1 to VCOn and it is tuned with the reference clock φ r inputted from the external side of chip and oscillates at the higher frequency (for example, 16 times). The clock of 10 GHz before frequency division is supplied as the operation clock to the multiplexer 122 of FIG. 1. Although eliminated in FIG. 2, the buffer circuits BUF1 to BUFn (refer to FIG. 3) to shape the waveform by receiving an output of each voltage-controlled oscillator are provided at the successive stage of the voltage-controlled oscillators VCO1 to VCOn.

The selector 12 of this embodiment is comprised, as illustrated in FIG. 3, of the circuit formed by connecting, in multiple stages, the discrete selector circuits SEL1, SEL2, . . . which can selectively pass any one of the signals of two systems. Namely, in the case where only one is selected from n voltage-controlled oscillators, the n/2 discrete selector circuits SEL1 to SELi (i=n/2) are provided in the initial stage, the n/4 discrete selector circuits are provided in the next stage and one discrete selector circuit SELx is provided in the last n/2 stage. For example, in the case where the eight voltage-controlled oscillators are prepared, the seven discrete selector circuits in total are provided, namely four selector circuits are provided in the initial stage, two circuits in the next stage and one circuit in the next stage. During the circuit operation, the control voltage is always applied from the selector control unit 14 to a plurality of discrete selector circuit SEL1, SEL2, . . . and thereby the discrete selector circuit SEL1, SEL2, . . . are always in the condition, during operation of the circuit, to select the same signal path. A common control voltage is applied to a plurality of selector circuits provided in the same stage and thereby a half signal path passing the discrete selector circuit is selected for each stage and only one signal path is defined effective in the last stage. A circuit structure of these discrete selector circuits SEL1, SEL2, . . . will be explained later.

Although detail circuit structure will be explained later, the fuse switch circuit 13 sets a pair of the voltage-controlled oscillator and buffer circuit used to the operation enabling condition, while another pair of voltage-controlled oscillator and buffer circuit to the operation disabling condition among a plurality of the voltage-controlled oscillators VCO1 to VCOn and the buffer circuits BUF1 to BUFn provided corresponding to such oscillators depending on the ON/OFF (non-continuity) condition of the fuse provided in the circuit. In more practical, a current of voltage-controlled oscillator and buffer circuit is supplied or cut off depending on the ON/OFF condition of fuse to set the operation enabling condition or operation disabling condition. The fuse is controlled to ON or OFF condition, for example, with the probe test after the formation of wafer.

The selector control unit 14 is a logic circuit for generating the control voltage to select the discrete selector circuit SEL1, SEL2, . . . in the selector 12 to allow only the signal of the voltage-controlled oscillator in the operation enabling condition to pass the selector 12 based on the condition of the fuse switch provided within the fuse switch circuit 12. As explained above, since the equal control voltage is outputted to the discrete selector circuit SEL1, SEL2, . . . of the same stage in the selector 12, the selector control unit 14 generates the control signals as many as the number of stages of the discrete selector circuits SEL1, SEL2, . . . These control voltages are respectively outputted to each stage of the discrete selectors SEL1, SEL2 . . . of the selector 12 as the complementary differential voltage.

A loop-filter LPF is comprised of an integral circuit for converting an error signal Ve which is changing depending on a phase difference between the reference clock φ r and feed-back signal φ b outputted, for example, from the phase detector PHC into a DC voltage, and an amplifying circuit for amplifying such voltage. However, a resistor and a capacitor forming the integral circuit are connected to the external terminal provided to the chip as the externally provided elements and the characteristic of the loop-filter can be changed by adjusting the resistance value and capacitance value of these externally provided elements.

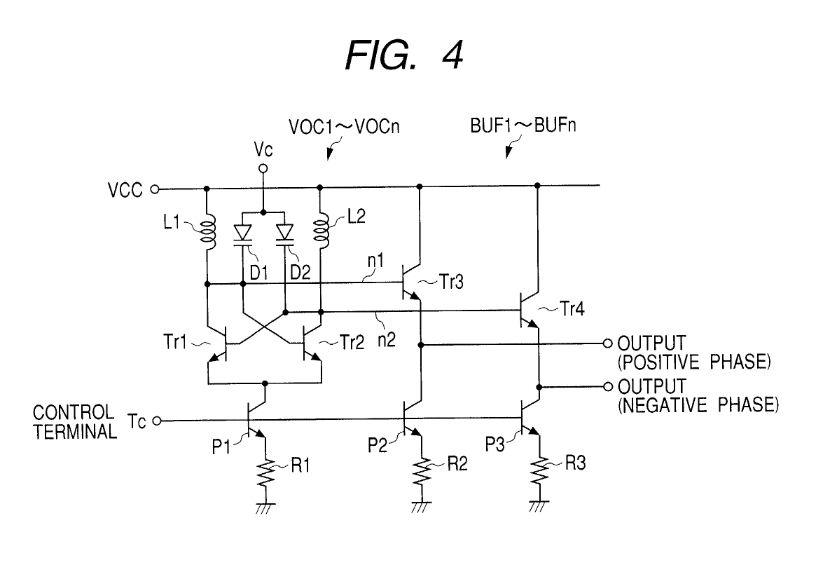

FIG. 4 is a diagram illustrating an example of a circuit structure of the voltage-controlled oscillator and buffer circuit.

A voltage-controlled oscillator is provided with spiral inductors L1, L2 that are formed by forming the wiring in the spiral shape and varactor diodes (capacitance variable diodes D1, D2) operating as a capacitance element when an inverse voltage is applied to the PN junction and changing the capacitance value depending on an amplitude of the inverse voltage. The collector of one transistor Tr1 to form the feedback loop is connected to the junction node n1 of the one inductor L1 and diode D1, while the collector of the other transistor Tr2 to form the feedback loop is connected to the junction node n2 of the other inductor L2 and diode D2. The power source voltage Vcc is impressed to each one end of each of the inductors L1, L2, while the control voltage Vc from the loop-filter LPF is impressed to each of the other ends of each of the diodes D1, D2.

In the voltage-controlled oscillator, the diode D1, inductor L1 and transistor Tr1 and diode D2, inductor L2 and transistor Tr2 operates in the pairs for oscillation through the mutual operation. That is, when the transistor Tr1 is in the ON condition, an electromotive force is accumulated in the inductor L1 and the diode D1 is discharged, while when the transistor Tr1 is in the OFF condition, the diode D1 is charged with the electromotive force of the inductor L1. The base of the transistor Tr1 is connected to the connection node n2 of the adjacent diode D2 and inductor L2, and the adjacent diode D2 and inductor L2 also operate in the same manner because the phase is deviated by 180 degrees. Therefore, two pairs of resonance circuits oscillate in the negative phase and identical frequency with the mutual operations of these elements. Accordingly, differential signals of the same frequency are outputted to the output nodes n1, n2. The oscillation frequency is determined by the inductance L of the inductors L1, L2 and capacitance value C of the diodes D1, D2 as 1/{2π√(L×C)}. The capacitance value C of the varactor diodes D1, D2 is changed and the oscillation frequency is also changed when the control voltage Vc is changed.

The buffer circuit is structured with two sets of emitter-follower circuits including a couple of grounded-collector type transistors Tr3, Tr4 for receiving a differential output signal from the voltage-controlled oscillator at the base and outputting the signal received with the transistors Tr3, Tr4 through the impedance conversion.

In the voltage-controlled oscillator VCO1 and buffer circuit BUF1 of FIG. 4, the transistors P1, P2, P3 and resistors R1, R2, R3 which become the constant current source are provided in the ground (second power source voltage) side. These transistors P1, P2, P3 are connected in common to the base and current supply is controlled with the control voltage impressed to the control terminal Tc. The control voltage is applied to this control terminal Tc from the fuse switch circuit 13

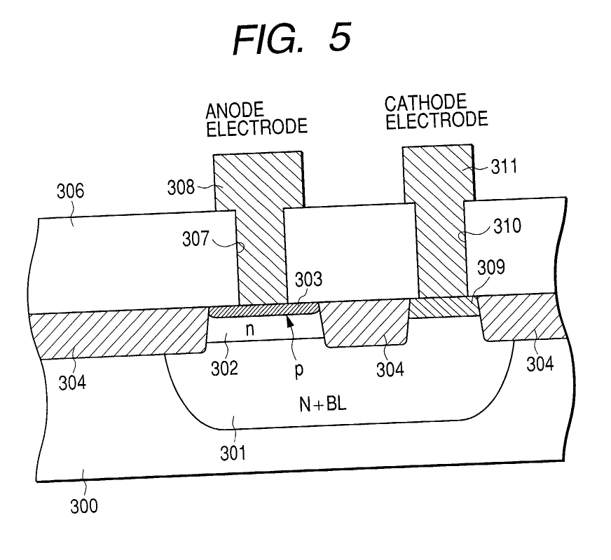

FIG. 5 illustrates an example of structure of the cross-section of the varactor diode D1.

In the same figure, 300 defines a P-type semiconductor substrate; 301, an N-type well region formed by diffusing the n-type impurity in the higher concentration; 304, a field oxide film; 302, an N-type region formed, for example, with the epitaxial growth; 303, a P-type region formed with diffusion at the surface of 302; 309, a metal film; 306, an interlayer insulating film; 307 and 310, contact holes formed on the interlayer insulating film 306; 308, an anode electrode formed of aluminum; and 311, a cathode electrode. These structures can be formed with the bipolar process of the same process as the base, collector, base electrode and collector electrode of the bipolar transistor Tr.

In the case where the varactor diode D1 has the structure explained above, its capacitance value changes depending on the area of the N-type region 302 and the P-type region 303 forming the PN-junction and the PN-junction characteristics such as interface characteristic and impurity concentration. Area can be formed comparatively with less fluctuation with an ordinary process but the PN-junction characteristic such as interface characteristic and impurity concentration fluctuates depending on the processes. Therefore, in the varactor diode D1 as explained above, the capacitance value fluctuates in some cases by almost 10 to 20% due to the ordinary fluctuation of process.

In the PLL circuit 10 of the present invention, a plurality of voltage-controlled oscillators to be provided in the VCO forming part 11 are designed by changing little by little the area of the PN-junction of the varactor diodes D1, D2 in every voltage-controlled oscillator and thereby the capacitance value is also changed little by little in every voltage-controlled oscillator. Deviation of the PN-junction characteristic due to the fluctuation of process is generated in the same direction within the adjacent range on the single wafer. Therefore, if process fluctuation is generated, a relative ratio of the capacitance value of each varactor diode does not change so much in the case where the area of PN-junction is changed in the stage of design.

Here, characteristics of a plurality of voltage-controlled oscillators in the design stage and change of characteristic due to process fluctuation will be explained.

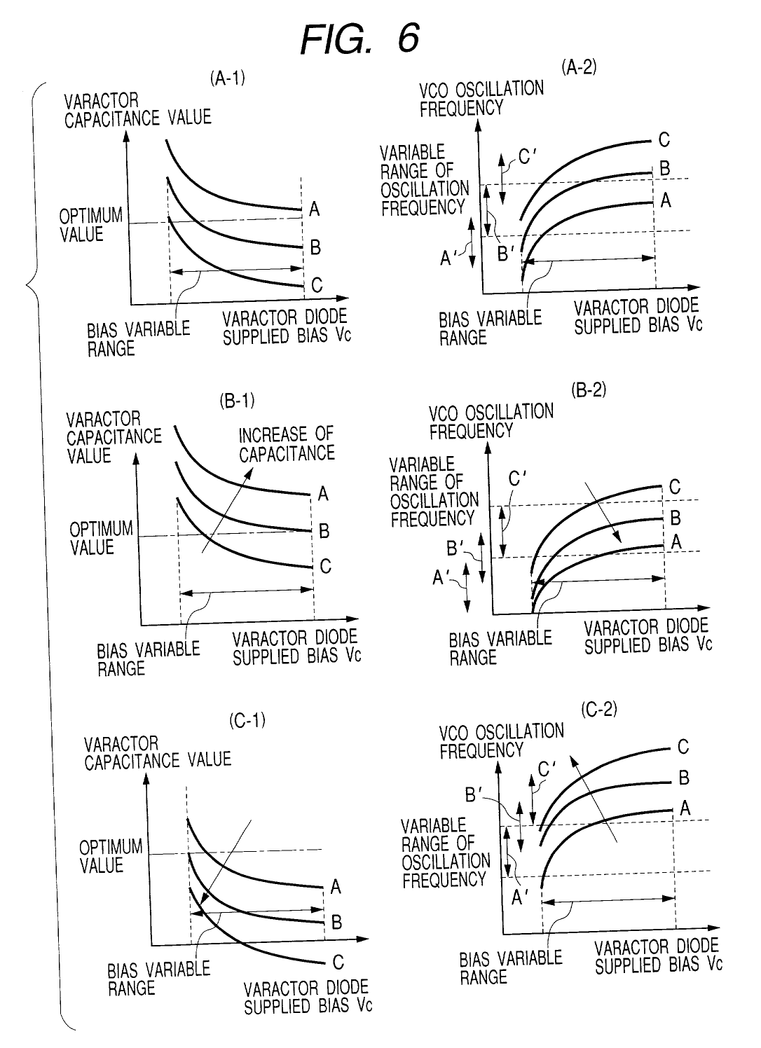

FIG. 6 is an explanatory diagram indicating change of the oscillation frequency of each voltage-controlled oscillator due to fluctuation of capacitance. (A-1) to (C-1) are graphs indicating the relationship between the control voltage Vc applied to the anodes of the varactor diodes C1, C2 and the capacitance values of the varactor diodes C1, C2, while (A-2) to (C-2) are graphs indicating the relationship between the control voltage Vc, namely the bias applied to the varactor diode and the oscillation frequency of the voltage-controlled oscillator. Here, three voltage-controlled oscillators (A, B, C) are used as the voltage-controlled oscillators VCO1 to VCOn.

In the PLL circuit 10 of this embodiment, as illustrated in FIG. 6(A-1), the capacitance values of the varactor diodes D1, D2 are designed to change little by little in a plurality of voltage-controlled oscillators (A, B, C). When the capacitance values of the diodes D1, D2 are determined as designed, the variable characteristic of the oscillation frequency of the voltage-controlled oscillator (A, B, C) is attained as illustrated in FIG. 6(A-2). In these graphs, the bias variable range is identical to the variable range of the control voltage Vc outputted from the loop filter LPF, and the variable range of the oscillation frequency of the voltage-controlled oscillator corresponding to such variable range becomes identical to the frequency variable range of each voltage-controlled oscillator. In these graphs, the frequency variable range of the voltage-controlled oscillator (A, B, C) is indicated as A′, B′ and C′.

Deviation of capacitance value of the varactor diodes D1, D2 in the design stage is determined adequately, considering fluctuation by process, accuracy of the obtained frequency variable range and the number of voltage-controlled oscillators to be formed, but the upper limit value and lower limit value of the adjacent ranges of the frequency variable ranges of the voltage-controlled oscillators (for example, A′ and B′ or B′ and C′ ) are designed to continue or overlap with each other.

In the case where the capacitance can be obtained as designed without any process fluctuation, the variable ranges as illustrated in FIGS. 6(A-1) and 6(A-2) can be obtained for the capacitance value of the varactor diode of the voltage-controlled oscillator and oscillation frequency thereof. In this case, the voltage-controlled oscillator which can obtain the desired frequency variable range has the center characteristic curve B and the PLL circuit 10 can be operated in the desired characteristic by setting the fuse switch to use this voltage-controlled oscillator.

On the other hand, if capacitance of varactor diode increases due to the process fluctuation, the voltage-controlled oscillator has the capacitance value of the varactor diode and variable range of oscillation frequency as illustrated in FIGS. 6(B-1) and 6(B-2). Capacitance of the voltage-controlled oscillator indicated with the characteristic curve B which is designed to become the adequate value when there is no process fluctuation exceeds the desired value and the capacitance value of the voltage-controlled oscillator indicated with the characteristic curve C which is designed with deviation from the desired value is then used as the desired value in place of above excessive capacitance value. As a result, the frequency variable range B′ of the voltage-controlled oscillator of the characteristic curve B is rather below the desired value and the frequency variable range C′ of the voltage-controlled oscillator of the characteristic curve C may be used as the desired value. Accordingly, the output of desired characteristic can be obtained from the PLL circuit 10 by setting the fuse switch to use the voltage-controlled oscillator having such desired value.

On the contrary, if the capacitance value of varactor diode is reduced due to the process fluctuation, the capacitance value of varactor diode of each voltage-controlled oscillator and oscillation frequency variable range as illustrated in FIGS. 6(C-1) and 6(C-2) can be obtained. In this case, the voltage-controlled oscillator showing the characteristic curve A can obtain the desired frequency variable range and the desired characteristic can be attained by setting the fuse switch to use this voltage-controlled oscillator.

FIG. 8 illustrates a practical circuit example of the discrete selector circuits SEL1, SEL2, . . . forming the selector 12 illustrated in FIG. 3.

The discrete selector circuit SEL1, SEL2, . . . of this embodiment is formed of the bipolar series gate and selects the differential signal of only one system among the differential signals CI1, /CI1, CI2, /CI2 of two systems inputted from the preceding stage depending on the selection control signals SEL, /SEL and outputs the differential output signals OUT, /OUT to the successive stages. The transistors Tr6 and Tr7 are connected in common at the emitters and are then connected to the collector of the transistor Tr10. The transistors Tr8 and Tr9 are connected in common at the emitters and are then connected to the collector of the transistor Tr11. The transistors Tr10 and Tr11 are connected in common at the emitter and are then connected to the collector of the constant current transistor Tr13.

In FIG. 8, a voltage Vc1 applied to the base of transistor Tr13 is the ON/OFF control voltage for making active/non-active the selector circuit SEL1. During operation of the optical transfer transceiver 100, the high level control voltage Vc1 is always applied to make active the selector circuit SEL1.

The selection signals SEL, /SEL supplied from the selector control unit 14 (FIG. 3) are connected to the bases of the transistors Tr10, Tr11 and the selection path is determined when any one of transistors turns ON. Namely, when the selection signal SEL is in the high level and the other selection signal /SEL is in the low level, the transistor Tr10 turns ON and the transistor Tr11 turns OFF. Accordingly, the transistors Tr6, Tr7 to which the differential signals CI1, /CI1 of the first system are inputted are set active to output the output differential signals OUT, /OUT based on the differential signals CI1, /CI1. In the contrary case, the output differential signals OUT, /OUT based on the differential signals CI2, /CI2 of the second system are outputted. Output of the voltage-controlled oscillator is supplied via the buffer circuit as the differential signals CI1, /CI1 and CI2, /CI2 and an output of any voltage-controlled oscillator is selected and transmitted.

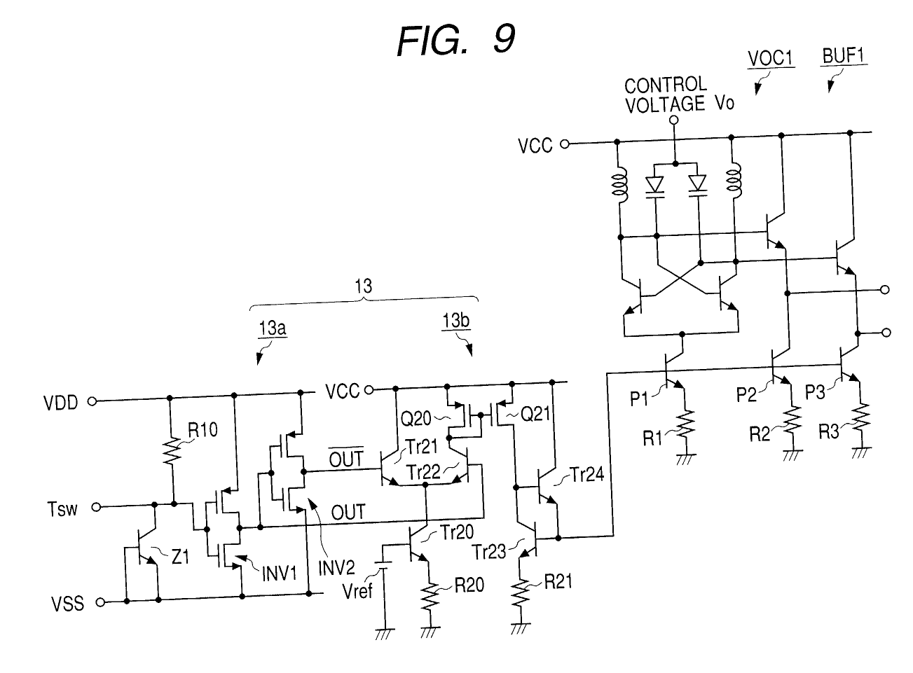

FIG. 9 illustrates the relationship between a partial circuit example of the fuse switch circuit 13 of FIG. 3 and the voltage-controlled oscillator.

The fuse switch circuit 13 is comprised of a fuse switch 13a and a constant current circuit 13b which are provided on the 1:1 basis for a plurality of voltage-controlled oscillators VCO1 to VCOn. Namely, the fuse switch circuit 13 is provided with the sets of the fuse switch 13a and constant current circuit 13b of FIG. 9 as many as the number of voltage-controlled oscillators VCO1 to VCOn.

The fuse switch 13a is provided with a switch Tsw which may be in contact with a probe used for the probe inspection, allowing that a sufficiently large resistor R10 is connected between the switch terminal Tsw and positive power source voltage VDD, while a transistor is connected between the switch terminal Tsw and negative power source voltage VSS in view of defining the base/collector junction as the zener fuse Z1. Moreover, the voltage of switch terminal Tsw is inputted to the two CMOS inverters INV1, INV2 to generate and output the differential output signals OUT and /OUT. These differential output signals OUT, /OUT are outputted to the constant current circuit 13b of the next stage. Unlike the voltage-controlled oscillator formed by the bipolar process and the constant current circuit 13b explained later, the fuse switch 13a is formed by the CMOS process. It is of course possible to form the fuse switch with the bipolar process.

In the fuse switch 13a, when the switch terminal Tsw is in the open condition, a current does not flow into the zener fuse Z1. Therefore, the voltage of the switch terminal Tsw becomes equal to VDD and the output signal OUT in the positive phase side of the fuse switch 13a becomes low level. In this case, the power source is not supplied to the corresponding voltage-controlled oscillator VCO1. Meanwhile, when the low level voltage is externally applied to the switch terminal Tsw, the output signal OUT in the positive phase side of the fuse switch 13a becomes high level. In this case, the power source is supplied to the corresponding voltage-controlled oscillator VCO1.

Moreover, when a voltage higher than the constant level is applied to the switch terminal Tsw, the PN-junction of the Zener fuse Z1 may be broken. Breakdown of PN-junction makes conductive the Zener fuse Z1 and since the resistor R10 is sufficiently large, a node voltage of the switch terminal Tsw becomes almost equal to VSS. Accordingly, the power source may be supplied to the corresponding voltage-controlled oscillator VCO1.

Namely, in the fuse switch 13a, supply of power source voltage to the corresponding voltage-controlled oscillator is cut off, the voltage-controlled oscillator is set to the non-active condition and the power source voltage is supplied to the corresponding voltage-controlled oscillator by blowing out the fuse under the condition that the switch terminal Tsw is in the open condition and the fuse is not blown out. Moreover, if the fuse is not blown out, the power source voltage can be supplied to the corresponding voltage-controlled oscillator and test operation may be conducted under the active condition of the voltage-controlled oscillator, just as in the case where the fuse is blown out, by applying externally the low level voltage to the switch terminal Tsw.

The constant current circuit 13b is constituted as the circuit for supplying a constant current to the voltage-controlled oscillator VCO1 with the differential input stage having the emitter-coupled transistors Tr21, Tr22 and the current Miller circuits of two stages consisting of the current-Miller connected MOSFET Q20, Q21 and transistors Tr23, P1. The constant current circuit 13b receives a differential output from the fuse switch 13a with the bases of a couple of input transistors Tr21, Tr22. When one input transistor Tr22 is turned ON, a current flowing into the constant current transistor Tr20 also flows into the MOSFET Q20 and also flows into the transistor Tr23 from the MOSFET Q21 owing to the current Miller effect.

A current of the same level as this current flows into the power supply transistor P1 of the voltage-controlled oscillator VCO1 which is current-Miller connected with the transistor Tr23 and the transistors P2, P3 of the buffer circuit BUF1 to active and operate the voltage-controlled oscillator VCO1 and buffer circuit BUF1.

Moreover, if the fuse is not blown out, a current does not flow into the voltage-controlled oscillator and buffer circuit, setting the circuit to the operation disabling condition.

Several variations may be considered for the fuse of the fuse switch.

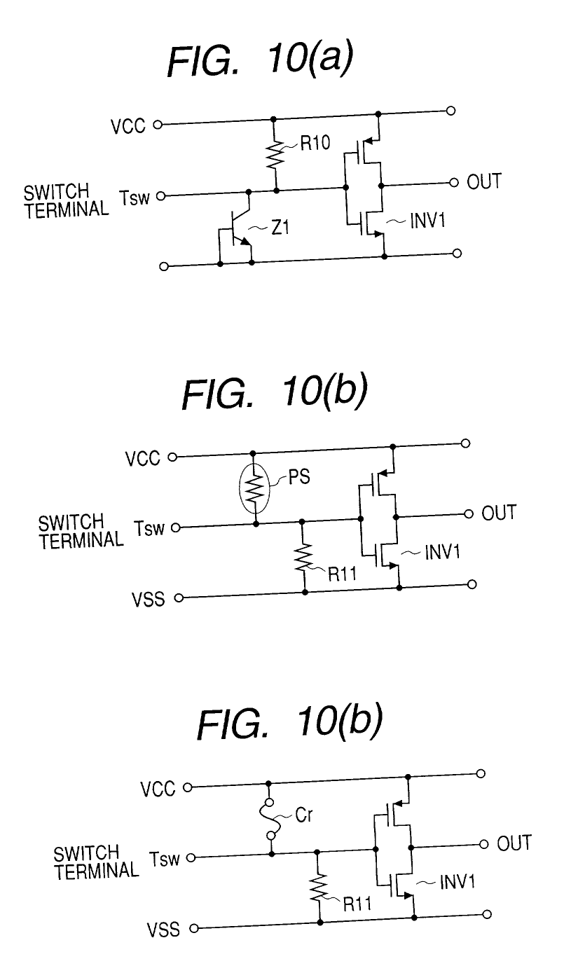

FIG. 10 illustrates variations of the fuse circuit.

FIG. 10(a) illustrates an example using the Zener fuse Z1 explained above. Junction breakdown may be generated in the Zener fuse Z1 by giving a high level voltage to the witch terminal Tsw.

FIG. 10(b) illustrates an example using a polysilicon fuse PS which is formed by forming the polysilicon resistor in the predetermined width. In this case, a current is cut off when the fuse blows. Therefore, unlike the case of Zener fuse Z1 of (a), the polysilicon fuse PS is provided between the switch terminal Tsw and the power source voltage VDD, and a sufficiently large resistor R11 is provided between the switch terminal Tsw and power source voltage VSS.

Even in this example, the circuit operation is almost identical to that when the Zener fuse Z1 is used. That is, under the condition that the switch terminal Tsw is opened, the voltage of switch terminal Tsw becomes high level and the output signal OUT in the positive phase side of the fuse switch 13a becomes low level. In this case, the power source voltage is not supplied to the corresponding voltage-controlled oscillator VCO1. Moreover, when the low level voltage is applied externally to the switch Tsw, the output signal OUT in the positive phase side of the fuse switch 13a becomes high level and the power source voltage is applied to the corresponding voltage-controlled oscillator VCO1.

Moreover, it is preferable to blow out the polysilicon fuse PS through thermal breakdown thereof by applying the voltage higher than the constant level to the switch terminal Tsw for the predetermined period. Otherwise, it is also possible to blow out the fuse through external irradiation of laser beam. When the polysilicon fuse PS blows out, the node voltage of the switch Tsw becomes identical to the power source voltage VSS, and the power source voltage is supplied to the corresponding voltage-controlled oscillator VCO1.

FIG. 10(c) illustrates an example using a chromium fuse Cr. Circuit operation of this example is similar to the case where the polysilicon fuse PS is used. This chromium fuse Cr can be blown out through irradiation of laser beam from the external side.

Next, the process after manufacture of wafer of the optical transfer transceiver 100 of this embodiment will be explained.

In the optical transfer transceiver 100 of this embodiment, it is requested to conduct the selection process in which the voltage-controlled oscillator having the optimum frequency variable range is identified from a plurality of voltage-controlled oscillators VCO1 to VCOn after manufacture of the wafer, and this voltage-controlled oscillator is allowed to operate, while the other voltage-controlled oscillators are not allowed to operate. This process can be realized with the probe test (P test) after manufacture of the wafer.

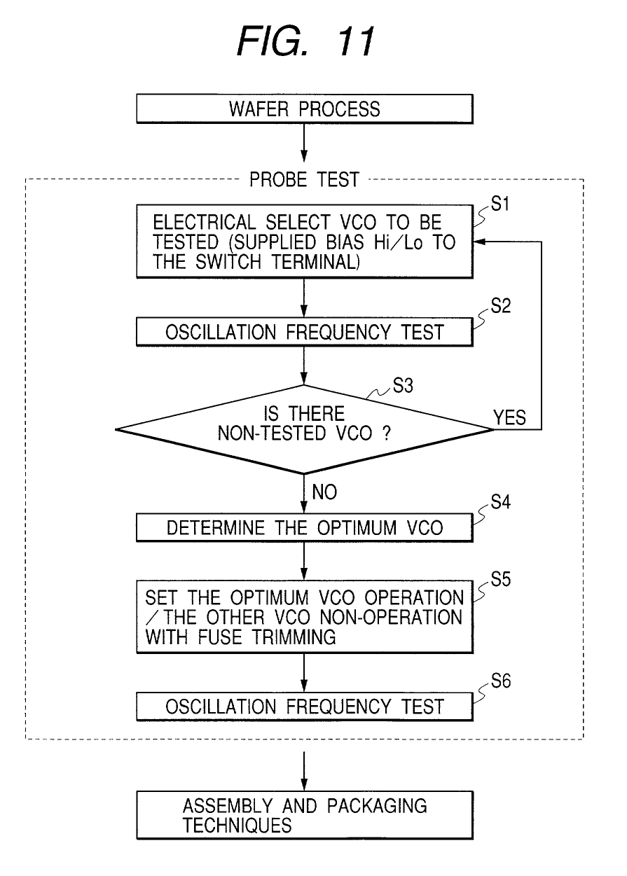

FIG. 11 illustrates a flowchart of the processing procedures for selecting the voltage-controlled oscillator in the probe test.

The selection process is started (step S1) to set only one voltage-controlled oscillator among a plurality of oscillators VCO1 to VCOn to the operation enabling condition while the other oscillators to the operation disabling condition with selective application of voltage from the probe. In more practical, independent probe is applied to the all switch terminals Tsw of a plurality of fuse switches 13a and a low level voltage is applied only to the switch terminal Tsw corresponding to the voltage-controlled oscillator to be tested, while the other switch terminals Tsw are opened.

Accordingly, the power source voltage is selectively applied only to one oscillator among a plurality of voltage-controlled oscillators VCO1 to VCOn of the VCO forming part 11 and thereby only the selected voltage- controlled oscillator (VCO circuit) executes the oscillating operation. Here, the oscillation frequency of this voltage-controlled oscillator is measured (step S2).

It is determined whether the oscillation frequency measurement of step S2 has been conducted for all voltage- controlled oscillator or not (step S3) and the processes of the steps S1, S2 are repeated until the measurement is completed for all voltage-controlled oscillators.

When the measurement of oscillation frequency is completed for all voltage-controlled oscillators, the voltage-controlled oscillator having the optimum oscillation frequency is determined by comparing the measured values (step S4).

Here, the predetermined high voltage is applied to the switch terminal Tsw of the fuse switch corresponding to the optimum voltage-controlled oscillator in order to blow out or break the conductivity of the fuse within the fuse switch (step S5). Accordingly, only the optimum voltage-controlled oscillator becomes ready for operation and the other voltage-controlled oscillators are in the operation disabling condition.

Thereafter, the voltage-controlled oscillator, which has become ready for operation because the fuse blows out, is caused to oscillate in order to confirm that the desired oscillation frequency is obtained by inspecting the oscillation frequency (step S6). When the normal operation can be confirmed, the post-process is started.

As explained above, according to the PLL circuit 10 of this embodiment, if the frequency variable range of the voltage-controlled oscillator is deviated due to the process fluctuation, the voltage-controlled oscillator having the desired frequency variable range can be found out from a plurality of voltage-controlled oscillators of different center frequencies with higher probability. Therefore, if the LC resonance type voltage-controlled oscillator having excellent phase noise characteristic but having narrow frequency variable range is employed, the PLL circuit 10 having excellent phase noise characteristic and desired frequency characteristic can be manufactured by identifying the optimum oscillator from a plurality of voltage-controlled oscillators and then setting such voltage-controlled oscillator to the operation enabling condition with the fuse switch circuit 13 and selector 12. Accordingly, the optical transfer transceiver 100 comprising the PLL circuit 10 has such a higher performance that jitter in the operation clock can be reduced and deterioration of transmitting waveform can also be reduced, resulting in the effect that manufacturing yield can be improved.

Moreover, since this embodiment is provided with a structure to disable or enable the supply of power source voltage to the voltage-controlled oscillator and buffer circuit in the next stage with the fuse switch 13a as the structure to select a plurality of voltage-controlled oscillators, it is no longer required to select the voltage-controlled oscillator in the user side using the optical transfer transceiver 100 and thereby selection error can be avoided. In addition, since the unused voltage-controlled oscillators are set to the operation disabling condition, deterioration by resonance of characteristic of PLL circuit and generation of noise can also be avoided.

Moreover, as the structure to select only one oscillator from a plurality of voltage-controlled oscillators, since a selector 12 is provided to supply the power source voltage to only one voltage-controlled oscillator and shut off the power source to the other voltage-controlled oscillators, supply the output of only the voltage-controlled oscillator to be operated to the PLL circuit 10 and electrically separate the output of the voltage-controlled oscillator to be not operated from the PLL circuit 10, disadvantages such as deterioration of characteristic of the PLL circuit and generation of noise due to the resonance of the voltage-controlled oscillator to which the power source voltage is not supplied can be eliminated.

In FIG. 11 based on FIG. 1, moreover in the step S5, it is also possible that a plurality of clocks are generated and only one of these clocks can be outputted through the operations in the user side after the shipping of the product. Namely, it is also possible to output only one fixed clock among a plurality of clocks which can be outputted with any one method that the clock selection signal can be inputted from the external side or that a register is provided within the circuit to follow the setting condition of such register.

The present invention has been explained based on the embodiment but the present invention is not limited thereto and allows various changes and modifications within the scope not departing from the subject matter.

For example, in this embodiment, the optical transfer transceiver 100 where the receiving circuit 110 and transmitting circuit 120 for optical transfer are mounted on one chip is explained as an example, but the present invention can also be applied effectively to the optical transfer unit wherein only the transmitting circuit 120 is mounted on one chip.

Moreover, it is not required to use both fuse switch circuit 13 and selector 12 as a means for selecting any one of a plurality of voltage-controlled oscillator. For example, it is also possible to use only the selector 12 or the fuse switch circuit 13. In addition, it is naturally possible to introduce a structure that an output of the non-operating voltage-controlled oscillator is separated from the circuit with a fuse switch in place of the selector 12. Moreover, it is also allowed to provide a structure that the supply of power source of the voltage-controlled oscillator not used is shut off only with electrical control without use of the fuse switch circuit 13. In this case, the voltage-controlled oscillator can be selected by inputting the select signal from the outside of chip.

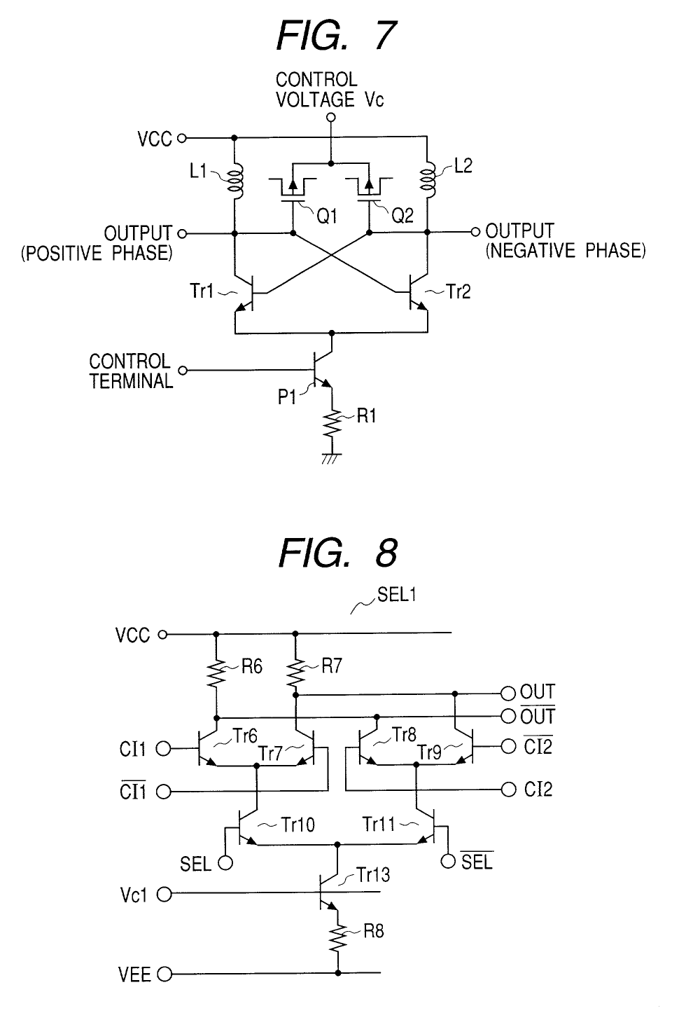

Moreover, the capacitance variable capacitor can take various structures in addition to the varactor diode which is formed with the bipolar process. FIG. 7 is the circuit diagram indicating the LC resonance type voltage-controlled oscillator utilizing the MOS capacitance. In this example, the voltage-controlled oscillator is formed using the capacitance between the gates of MOSFET Q1, Q2 and substrate in place of the varactor diode. In this case, the capacitance value can be increased or decreased by changing the substrate potential through application of the control voltage Vc to the well region of the MOSFET Q1, Q2 from the loop filter LPF.

Moreover, the LC resonance type voltage-controlled oscillator is not limited to the type of FIG. 4 and various types of voltage-controlled oscillators to realize resonance with inductor and capacitor may be used. In addition, as a method of using different center frequencies of the voltage-controlled oscillators, different areas of the PN-junction of varactor diode are used and different capacitance values are also used, but moreover it is also possible to use different diameters of spiral inductor and use different inductance values.

In above description, the present invention has been explained in regard to the optical transfer transceiver integrated circuit that is the application field as the background of the present invention. But, the present invention is not limited thereto and can also be utilized widely to all semiconductor integrated circuits mounting the PLL circuit.

The effects of the typical inventions disclosed in the present specification can be briefly explained as follows.

Namely, according to the present invention, if the frequency characteristic of the voltage-controlled oscillator is deviated due to the process fluctuation, the PLL circuit having excellent phase noise characteristic and desired characteristic can be realized by finding out and selecting the voltage-controlled oscillator having the desired frequency characteristic from a plurality of oscillators having different center frequencies.

What is claimed is:

1. A semiconductor integrated circuit provided with a PLL circuit comprising:
a voltage-controlled oscillator which oscillates in the frequency depending on an applied control voltage; and
a phase comparator which compares a phase of an oscillation output signal of said voltage-controlled oscillator with a phase of a predetermined frequency, wherein said PLL circuit includes said voltage-controlled oscillator applied an output voltage of the circuit which outputs a voltage depending on a phase difference based on an output of said phase comparator and is capable of controlling oscillation frequency of said voltage controlled oscillator,
wherein said semiconductor integrated circuit further comprising:
a plurality of voltage-controlled oscillators having different center frequencies of the frequency variable range to provide continuous or overlapped frequency variable range with each other; and selecting means to select one voltage-controlled oscillator to the fixed operation enabling condition from a plurality of voltage-controlled oscillators.

2. A semiconductor integrated circuit provided with a PLL circuit comprising:
a voltage-controlled oscillator which oscillates in the frequency depending on an applied control voltage; and
a phase comparator which compares a phase of an oscillation output signal of said voltage-controlled oscillator with a phase of a predetermined frequency, wherein said PLL circuit includes said voltage-controlled oscillator applied an output voltage of the circuit which outputs a voltage depending on a phase difference based on an output of said phase comparator and is capable of controlling oscillation frequency of said voltage controlled oscillator,
wherein said voltage-controlled oscillator comprising:
a plurality of resonance type oscillators respectively including a resonance circuit having inductor and capacitor to provide different center frequencies of frequency variable range; and
a selecting unit for fixedly selecting a resonance type oscillator from a plurality of resonance type oscillators.

3. A semiconductor integrated circuit according to claim 2, wherein a plurality of said resonance type oscillators provides the continuous or overlapped frequency variable range.

4. A semiconductor integrated circuit according to claim 2,
wherein said selecting unit comprises a fuse circuit including a plurality of fuses corresponding to a plurality of said resonance type oscillators, wherein one of fuses of said fuse circuit is broken in connection or conductivity and thereby the power source voltage is supplied only to one resonance type oscillator among a plurality of said resonance type oscillators.

5. A semiconductor integrated circuit according to claim 2, wherein said selecting unit includes a selector circuit, and
wherein said selector circuit supplies an output of one of said resonance type oscillators to said phase comparing circuit depending on the control signal to shut off the outputs of the other resonance type oscillators.

6. A semiconductor integrated circuit according to claim 4,
wherein a plurality of said resonance type oscillators respectively include transistors for power source supply, and
wherein said fuse circuit is capable of making conductive the power source supply transistor of the resonance type oscillator corresponding to the broken fuse and making non-conductive the power source supply transistor of the resonance type oscillator corresponding to the non-broken fuse.

7. A semiconductor integrated circuit according to claim 4,
wherein the output sides of a plurality of said resonance type oscillators respectively include the buffer circuits, and
wherein said fuse circuit sets, to the operation enabling condition, only one buffer circuit corresponding to the resonance type oscillator to which the power source voltage is supplied.

8. A semiconductor integrated circuit according to claim 6,
wherein said inductor includes a spiral type inductor formed of the wiring formed in the spiral shape on a semiconductor substrate, and
wherein said capacitor includes a variable capacitance diode formed of the PN-junction connected in an inverse direction.

9. A semiconductor integrated circuit according to claim 7,
wherein said inductor includes a spiral type inductor formed of the wiring formed in the spiral shape on a semiconductor substrate, and
wherein said capacitor includes a variable capacitance diode formed of the PN-junction connected in an inverse direction.

10. An optical transfer unit on semiconductor substrate comprising:
a multiplexer for multiplexing a plurality of low-speed data signal inputted from an outside of a chip to output such data signal as a high-speed data signal; and
a PLL circuit providing the operation clock to said multiplexer based on the clock inputted from the outside,
wherein said PLL circuit comprising:
a plurality of voltage-controlled oscillators including a plurality of resonance circuits having a plurality of inductors and capacitors to oscillate at the frequency corresponding to the control voltage to be applied in order to provide different center frequencies of frequency variable range and continuous or overlapped frequency variable range in different center frequencies;
a selecting unit for selecting any one oscillator from a plurality of said voltage-controlled oscillators; and
a phase comparator for comparing the phase of the oscillation output signal of the selected voltage-controlled oscillator with the phase of said clock,
whereby an output voltage of the circuit for supplying a voltage depending on the phase difference based on an output of said phase comparator is applied to said selected voltage-controlled oscillator as the control voltage.

11. A semiconductor integrated circuit provided with a PLL circuit comprising:
a voltage-controlled oscillator which oscillates in the frequency depending on an applied control voltage; and
a phase comparator which compares a phase of an oscillation output signal of said voltage-controlled oscillator with a phase of a predetermined frequency, wherein said PLL circuit includes said voltage-controlled oscillator applied an output voltage of the circuit which outputs a voltage depending on a phase difference based on an output of said phase comparator and is capable of controlling oscillation frequency of said voltage controlled oscillator,
wherein said voltage-controlled oscillator comprising:
a plurality of resonance oscillators including resonance circuits having a plurality of inductors and capacitors and providing different center frequencies of the frequency variable range;
a first selecting circuit which is capable of selecting the predetermined number of clocks among a plurality of clocks provided from a plurality of said resonance oscillators; and
a second selecting circuit which is capable of selecting one clock among the predetermined number of clocks based on the information which is capable of being set from outside.
